(19) United States
(12) Patent Application Publication
(10) Pub. No.: US 2024/0313009 A1
(43) Pub. Date: Sep. 19, 2024

(54) SOLID-STATE IMAGING APPARATUS

(71) Applicant: SONY SEMICONDUCTOR SOLUTIONS CORPORATION, KANAGAWA (JP)

(72) Inventor: RYOTA WATANABE, KANAGAWA (JP)

(21) Appl. No.: 18/575,339

(22) PCT Filed: Feb. 15, 2022
(86) PCT No.: PCT/JP2022/005837

§ 371 Date: Dec. 29, 2023

(30) Foreign Application Priority Data
Jul. 13, 2021 (JP) 2021-115939

(51) Int. Cl. H01L 27/146; G01S 7/481; G01S 17/894

(52) U.S. Cl. CPC H01L 27/14603; G01S 7/4816; G01S 17/894; H01L 27/14623; H01L 27/14629; H01L 27/1463

(57) ABSTRACT

The present invention provides a solid-state imaging apparatus in which pixels are arranged in an array. Each the plurality of pixels includes: a pixel separator that defines an outer edge shape of the pixel and is formed between the adjacent pixels; a photoelectric converter that generates an amount of charge corresponding to light incident from the outside; a plurality of transistors, including a transfer transistor formed at one end of the photoelectric converter to transfer the charge generated by the photoelectric converter; a floating diffusion region formed around the photoelectric converter to temporarily store the charges generated and transferred by the photoelectric converter; and a shielding portion formed around the photoelectric converter to block light leaking from the photoelectric converter and directed toward the floating diffusion region. The plurality of transistors further includes: a reset transistor for resetting a potential of the floating diffusion region; and a feedback enable transistor connected to a feedback amplifier circuit for canceling out voltage noise of the reset transistor. The shielding portion blocks light directed toward a portion of the floating diffusion region formed near the feedback enable transistor.

### TECHNICAL FIELD

The present technology relates to a solid-state imaging apparatus.

### BACKGROUND ART

A solid-state imaging apparatus is a semiconductor apparatus that uses photoelectric conversion elements, such as photodiodes, constituting pixels (light-receiving pixels) for receiving light to convert the amounts of charges corresponding to the intensities of light imaged on the pixels into electrical signals. From the viewpoint of utilization efficiency of incident light, back-illuminated solid-state imaging apparatuses in which no metal wiring layer is disposed between a light incident surface (light-receiving surface) and a photoelectric conversion element are widely used.

In such back-illuminated solid-state imaging apparatuses, it has been known that crosstalk in which light incident on adjacent pixels mixes with each other occurs, resulting in deterioration in image quality such as a decrease in resolution, color reproducibility, and differences in brightness. Therefore, in order to avoid such deterioration in image quality due to crosstalk, a pixel separator having a trench structure is provided between pixels to electrically and optically separate the pixels. In addition, when light enters a floating diffusion region formed near a photoelectric conversion element within a pixel, unintended charges are generated. Thus, even if no charge is drawn from the photoelectric conversion element, an electrical signal based on an unintended charge is detected, which has a negative effect on image quality, especially in low-light conditions. Therefore, in order to prevent such a deterioration in image quality, it is necessary to take measures to prevent light from entering the floating diffusion region formed within the pixel.

For example, PTL 1 below discloses an imaging apparatus that suppresses stray light to a floating diffusion region that functions as a charge storage unit.

Furthermore, PTL 2 below discloses an imaging apparatus that can shield the charge storage unit from light at low cost while maintaining a charge transfer path from the photodiode to the charge storage unit.

Further, PTL 3 below discloses an imaging apparatus that can suppress the incidence of unnecessary light between adjacent pixel regions and exhibit better imaging performance.

### CITATION LIST

### Patent Literature

[PTL 1]
JP 2017-168566 A
[PTL 2]
WO 2018/083990 A1
[PTL 3]
JP 2020-194912 A

### SUMMARY

### Technical Problem

As described above, back-illuminated solid-state imaging apparatuses have a problem in that unintended light enters the floating diffusion region, which is a charge storage unit, and image quality deteriorates. In particular, in back-illuminated solid-state imaging apparatuses that are compatible with the indirect ToF method, it is necessary to arrange a large number of various transistor elements and the like around photoelectric conversion elements to distribute charges generated by photoelectric conversion elements in pixels to respective charge storage units according to the opening/closing timing of multiple gates, making the arrangement structure complicated.

For example, a feedback drive mechanism is provided in a pixel of a back-illuminated solid-state imaging apparatus for the purpose of noise canceling when resetting charges in a floating diffusion region. The arrangement of transistors that constitute this feedback drive mechanism will form an additional floating diffusion region.

However, none of the above-mentioned patent literature takes into account the entry of light into the additional floating diffusion region in which the transistors constituting the feedback drive mechanism are arranged. Therefore, there has been a problem of deterioration in image quality due to light entering the additional floating diffusion region.

Therefore, an object of the present disclosure is to propose a technology for reliably suppressing unintended light from entering a floating diffusion region formed in a pixel in a back-illuminated solid-state imaging apparatus.

More specifically, an object of the present disclosure is to propose a technology for reliably suppressing unintended light from entering an additional floating diffusion region formed near a transistor arranged in a pixel in a back-illuminated solid-state imaging apparatus.

In particular, an object of the present disclosure is to propose a technology for reliably suppressing unintended light from entering an additional floating diffusion region formed by a transistor that constitutes a feedback drive mechanism arranged in a pixel in a back-illuminated solid-state imaging apparatus.

### Solution to Problem

The present technology to solve the above problems includes the following invention specifying matters or technical features.

The present technology according to a certain aspect is a solid-state imaging apparatus including a pixel array unit in which a plurality of pixels are arranged in an array. Each the plurality of pixels includes: a pixel separator that defines an outer edge shape of the pixel and is formed between the adjacent pixels; a photoelectric converter that generates an amount of charge corresponding to light incident from the outside; a plurality of transistors, including a transfer transistor formed at one end of the photoelectric converter to transfer the charge generated by the photoelectric converter; a floating diffusion region formed around the photoelectric converter to temporarily store the charges generated and transferred by the photoelectric converter; and a shielding portion formed around the photoelectric converter to block light leaking from the photoelectric converter and directed toward the floating diffusion region. The plurality of transistors further includes: a reset transistor for resetting a potential of the floating diffusion region; and a feedback enable transistor connected to a feedback amplifier circuit for canceling out voltage noise of the reset transistor. The shielding portion blocks light directed toward a portion of the floating diffusion region formed near the feedback enable transistor.

Note that in the present disclosure, a “system” refers to a logical group of a plurality of apparatuses (or functional modules that realize specific functions), and there is no particular limitation as to whether or not each of the apparatuses and the functional modules is in a single casing.

Other technical features, objects, and effects or advantages of the present technology will become apparent through the following embodiments, which will be described with reference to the accompanying drawings. The effects described in the present disclosure are merely illustrative examples and are not limited thereto, and there may be other effects.

### BRIEF DESCRIPTION OF DRAWINGS

FIG. 1 is a block diagram illustrating an example of a schematic configuration of a solid-state imaging apparatus according to an embodiment of the present technology.

FIG. 2 is a diagram illustrating an example of a circuit configuration of pixels in a pixel array unit of a solid-state imaging apparatus according to a first embodiment of the present technology.

FIG. 3 is a diagram for explaining an example of the planar layout of each element forming a pixel in the pixel array unit of the solid-state imaging apparatus according to the first embodiment of the present technology.

FIG. 4 is a diagram showing an example of a schematic cross-sectional structure of the pixel shown in FIG. 3 taken along the IV-IV cross-section.

FIG. 5A is a diagram for explaining another example of the planar layout of each element forming a pixel in the pixel array unit of the solid-state imaging apparatus according to the first embodiment of the present technology.

FIG. 5B is a diagram for explaining still another example of the planar layout of each element forming a pixel in the pixel array unit of the solid-state imaging apparatus according to the first embodiment of the present technology.

FIG. 6 is a diagram illustrating an example of a circuit configuration of a pixel in a pixel array unit of a solid-state imaging apparatus according to a second embodiment of the present technology.

FIG. 7A is a diagram for explaining an example of a planar layout of each element forming a pixel in the pixel array unit of the solid-state imaging apparatus according to the second embodiment of the present technology.

FIG. 7B is a diagram for explaining another example of the planar layout of each element forming a pixel in the pixel array unit of the solid-state imaging apparatus according to the second embodiment of the present technology.

FIG. 7C is a diagram for explaining still another example of the planar layout of each element forming a pixel in the pixel array unit of the solid-state imaging apparatus according to the second embodiment of the present technology.

FIG. 7D is a diagram for explaining still another example of the planar layout of each element forming a pixel in the pixel array unit of the solid-state imaging apparatus according to the second embodiment of the present technology.

FIG. 7E is a diagram for explaining still another example of the planar layout of each element forming a pixel in the pixel array unit of the solid-state imaging apparatus according to the second embodiment of the present technology.

FIG. 7F is a diagram for explaining still another example of the planar layout of each element forming a pixel in the pixel array unit of the solid-state imaging apparatus according to the second embodiment of the present technology.

FIG. 8A is a diagram for explaining an example of a planar layout of each element forming a pixel in a pixel array unit of a solid-state imaging apparatus according to a third embodiment of the present technology.

FIG. 8B is a diagram for explaining another example of the planar layout of each element forming a pixel in the pixel array unit of the solid-state imaging apparatus according to the third embodiment of the present technology.

FIG. 8C is a diagram for explaining another example of the planar layout of each element forming a pixel in the pixel array unit of the solid-state imaging apparatus according to the third embodiment of the present technology.

FIG. 8D is a diagram for explaining another example of the planar layout of each element forming a pixel in the pixel array unit of the solid-state imaging apparatus according to the third embodiment of the present technology.

FIG. 9 is a diagram for explaining an example of a planar layout of each element forming a pixel in a pixel array unit of a solid-state imaging apparatus according to a fourth embodiment of the present technology.

FIG. 10 is a diagram showing an example of a schematic cross-sectional structure of the pixel shown in FIG. 9 taken along the X-X cross-section.

FIG. 11A is a diagram for explaining another example of the planar layout of each element forming a pixel in the pixel array unit of the solid-state imaging apparatus according to the fourth embodiment of the present technology.

FIG. 11B is a diagram for explaining still another example of the planar layout of each element forming a pixel in the pixel array unit of the solid-state imaging apparatus according to the fourth embodiment of the present technology.

FIG. 12A is a diagram for explaining still another example of the planar layout of each element forming a pixel in the pixel array unit of the solid-state imaging apparatus according to the fourth embodiment of the present technology.

FIG. 12B is a diagram for explaining still another example of the planar layout of each element forming a pixel in the pixel array unit of the solid-state imaging apparatus according to the fourth embodiment of the present technology.

FIG. 13A is a diagram for explaining an example of a planar layout of each element forming a pixel in a pixel array unit of a solid-state imaging apparatus according to a fifth embodiment of the present technology.

FIG. 13B is a diagram for explaining an example of a planar layout of each element forming a pixel in the pixel array unit of the solid-state imaging apparatus according to the fifth embodiment of the present technology.

FIG. 13C is a diagram for explaining an example of a planar layout of each element forming a pixel in the pixel array unit of the solid-state imaging apparatus according to the fifth embodiment of the present technology.

FIG. 13D is a diagram for explaining an example of a planar layout of each element forming a pixel in the pixel array unit of the solid-state imaging apparatus according to the fifth embodiment of the present technology.

FIG. 14A is a diagram for explaining an example of a planar layout of each element forming a pixel in the pixel array unit of the solid-state imaging apparatus according to the fifth embodiment of the present technology.

FIG. 14B is a diagram for explaining an example of a planar layout of each element forming a pixel in the pixel array unit of the solid-state imaging apparatus according to the fifth embodiment of the present technology.

FIG. 14C is a diagram for explaining an example of a planar layout of each element forming a pixel in the pixel array unit of the solid-state imaging apparatus according to the fifth embodiment of the present technology.

### DESCRIPTION OF EMBODIMENTS

Embodiments of the present technology will be described below with reference to the drawings. However, the embodiments described below are just illustrative examples and are not intended to exclude various modifications and applications of techniques which will not explicitly be described below. The present technology can be implemented with various modifications (such as combinations of the embodiments, for example) without departing from the gist thereof. In the following description of the drawings, the same or similar portions are denoted with the same or similar reference signs. Also, the drawings are schematically illustrated and do not necessarily coincide with actual dimensions, ratios, and the like. In addition, the drawings include portions where dimensional relationships and ratios differ between the drawings in some cases. Note that in the present disclosure, the present technology will be explained by dividing it into the following embodiments.
1. First embodiment (basic configuration example)
2. Second embodiment (configuration example using two charge drain transistors)
3. Third embodiment (configuration example with another layout of source follower circuit)
4. Fourth embodiment (configuration example using vertical transistors)
5. Fifth embodiment (configuration example using dummy semiconductor structure)
6. Sixth embodiment (configuration example when no feedback enable transistor is used)

### 1. First Embodiment

The present embodiment is characterized in that a solid-state imaging apparatus includes a pixel having a structure that suppresses light from entering a floating diffusion region formed around a photoelectric converter such as a single photodiode. In particular, the present embodiment describes a pixel having a structure that suppresses light from entering floating diffusion regions formed by a feedback enable transistor and a switching transistor, respectively.

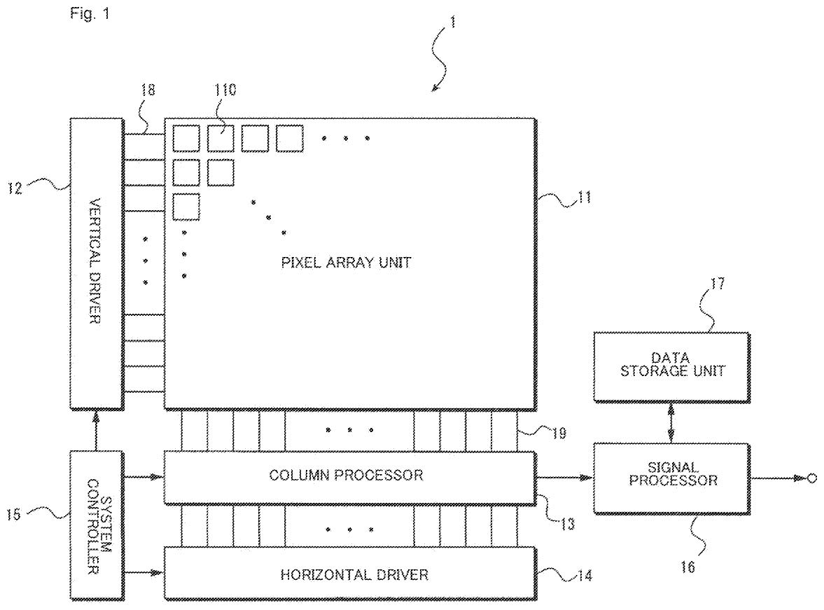

FIG. 1 is a block diagram illustrating an example of a schematic configuration of a solid-state imaging apparatus according to an embodiment of the present technology. A solid-state imaging apparatus 1 is a semiconductor apparatus that uses photoelectric conversion elements, such as photodiodes, constituting pixels to convert the amounts of charges corresponding to the intensities of light imaged on the pixels into electrical signals and output the electrical signals as pixel data. The solid-state imaging apparatus 1 of the present disclosure is a back-illuminated solid-state imaging apparatus having a semiconductor element structure adapted to an indirect ToF method.

As illustrated in FIG. 1, the solid-state imaging apparatus 1 includes components including, for example, a pixel array unit 11, a vertical driver 12, a column processor 13, a horizontal driver 14, a system controller 15, a signal processor 16, and a data storage unit 17.

The pixel array unit 11 includes a group of pixels 110 as light-receiving elements arranged in an array in the horizontal direction (row direction) and the vertical direction (column direction). The pixel array unit 11 converts an amount of charge corresponding to the intensity of incident light imaged onto each pixel into an electrical signal, and outputs the electrical signal as a pixel signal. As described later, the pixel 110 includes a photodiode, several transistors, and the like formed in a semiconductor region. The pixel array unit 11 may include, for example, effective pixels arranged in a region that can receive actual light and dummy pixels arranged outside of the region and shielded by metal or the like. Although not shown, optical system elements such as a micro-on-chip lens and a color filter for condensing incident light are formed on each pixel of the pixel array unit 11.

The vertical driver 12 includes circuits such as a shift register and an address decoder. The vertical driver 12 supplies driving signals and the like to the pixels through a plurality of pixel driving lines 18 to drive the pixels of the pixel array unit 11, for example, simultaneously or for each row.

The column processor 13 reads pixel signals from the pixels through a vertical signal line (VSL) 19 for each pixel column of the pixel array unit 11 and performs noise removal processing, correlated double sampling (CDS) processing, analog-to-digital (A/D) conversion processing, and the like. The pixel signals processed by the column processor 13 are output to the signal processor 16. In the present disclosure, the vertical signal line (VSL) 19 is an example of a readout signal line.

The horizontal driver 14 includes circuits such as a shift register and an address decoder. The horizontal driver 14 sequentially selects pixels corresponding to the pixel columns of the column processor 13. By this selective scanning by the horizontal driver 14, pixel signals subjected to signal processing for each pixel in the column processor 13 are sequentially output to the signal processor 16.

The system controller 15 includes a circuit such as a timing generator that generates various timing signals. The system controller 15 controls the vertical driver 12, the column processor 13, and the horizontal driver 14 based on a timing signal generated by a timing generator (not shown), for example.

The signal processor 16 performs signal processing such as arithmetic processing on the pixel signals supplied from the column processor 13, while temporarily storing data in the data storage unit 17 as necessary, and outputs an image signal based on each pixel signal.

The solid-state imaging apparatus 1 is not limited to the configuration described above. As an example, in the solid-state imaging apparatus 1, the data storage unit 17 may be arranged after the column processor 13, and be configured to supply the pixel signals output from the column processor 13 to the signal processor 16 via the data storage unit 17. As another example, the solid-state imaging apparatus 1 may be configured such that the column processor 13, data storage unit 17, and signal processor 16 that are connected in cascade process the pixel signals in parallel.

The solid-state imaging apparatus 1 configured as described above is adapted, for example, to a distance image sensor device for acquiring a distance image based on distance information to an object. Such a distance image sensor device is configured, for example, as a system-on-chip (SoC) CMOS image sensor. As an example, a distance image sensor device is mounted on a vehicle and applied to an in-vehicle system that measures distance information to an object outside of the vehicle. As another example, the distance image sensor device is applied to a user interface that measures the distance to a user's finger or the like and recognizes the user's gesture based on the measurement result.

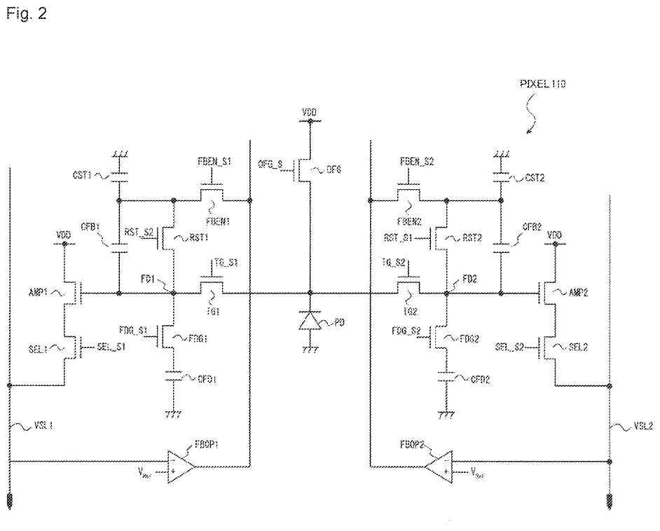

FIG. 2 is a diagram showing an example of the circuit configuration of pixels in the pixel array unit of the solid-state imaging apparatus according to the first embodiment of the present technology. That is, the figure shows an example of the circuit configuration of any one pixel (unit pixel) 110 among the plurality of pixels 110 that constitute the pixel array unit 11 of the solid-state imaging apparatus 1 shown in FIG. 1.

As shown in the figure, the pixel 110 includes a photoelectric converter PD made of, for example, a photodiode. Furthermore, in the present disclosure, in order to enable distance measurement using an indirect ToF method, the pixel 110 is configured to be able to distribute the charges generated by the photoelectric converter PD according to the intensity of the received light and output them as separate pixel signals.

That is, the pixel 110 of this example includes transfer transistors TG1 and TG2, additional capacitances CFD1 and CFD2, switching transistors FDG1 and FDG2, reset transistors RST1 and RST2, feedback enable transistors FBEN1 and FBEN2, feedback amplifier circuits FBOP1 and FBOP2, amplification transistors AMP1 and AMP2, selection transistors SEL1 and SEL2, and a charge drain transistor OFG. Furthermore, floating diffusion regions FD1 and FD2 are formed between the transfer transistors TG1 and TG2 and the amplification transistors AMP1 and AMP2, respectively. The transfer transistors TG1 and TG2, the switching transistors FDG1 and FDG2, the reset transistors RST1 and RST2, the feedback enable transistors FBEN1 and FBEN2, the selection transistors SEL1 and SEL2, and the charge drain transistor OFG are driven and controlled by the vertical driver 12. Note that in the figure, devices or elements shown in pairs, such as transfer transistors TG1 and TG2, are hereinafter referred to as transfer transistors TG unless it is necessary to distinguish them from each other. Further, in the present disclosure, the transfer transistors TG1 and TG2, and the like are described as a pair of transistors, but are not limited thereto, and may be configured as a set of three or more transistors.

In the present disclosure, each transistor in the pixel 110 is an NMOS transistor, but is not limited thereto. Further, all or at least some of these transistors are made of polycrystalline silicon (hereinafter referred to as “polysilicon”). Polysilicon is advantageous for reflecting or shielding light. In the present disclosure, a transistor having a vertical structure made of polysilicon can reflect or block light leaking from or passing through the photoelectric converter PD.

The transfer transistor TG is a switching transistor for transferring the charge generated by the photoelectric converter PD to the floating diffusion region FD. That is, the transfer transistor TG1 enters a non-conducting state (off state) when the voltage of the transfer driving signal TG_S1 supplied to its gate goes a LOW level, and enters a conducting state (on state) when the voltage of the transfer driving signal TG_S1 goes a High level. In this way, the transfer transistor TG1 transfers the charge generated by the photoelectric converter PD to the floating diffusion region FD1. In addition, the transfer transistor TG2 enters a non-conducting state (off state) when the voltage of the transfer driving signal TG_S2 supplied to its gate goes a LOW level, and enters a conducting state (on state) when the voltage of the transfer driving signal TG_S2 goes a High level. In this way, the transfer transistor TG2 transfers the charge generated by the photoelectric converter PD to the floating diffusion region FD1. The transfer driving signal TG_S1 and the transfer driving signal TG_S2 have a predetermined phase difference from each other, so that the charge generated by the photoelectric converter PD is transferred to the floating diffusion regions FD1 and FD2 at different timings.

The floating diffusion region FD functions as a charge storage unit that temporarily holds the charges generated by and transferred from the photoelectric converter PD. That is, in the present disclosure, the charges generated by the photoelectric converter PD are distributed and stored in the floating diffusion regions FD1 and FD2, respectively, by the operations of the transfer transistors TG1 and TG2 with a predetermined time difference. The charges stored in the floating diffusion regions FD1 and FD2 are read out at a predetermined timing as an electrical signal (pixel signal) with a voltage corresponding to the amount. Note that in the present disclosure, as described later, a portion of the floating diffusion region FD may be referred to as FD′ or FD″.

The switching transistor FDG is a switching transistor for coupling the additional capacitance CFD to the floating diffusion region FD according to the intensity of the received light. In other words, when the voltage of the FD driving signal FDG_S1 supplied to its gate goes a High level, the switching transistor FDG1 enters a conducting state, whereby the floating diffusion region FD1 and the additional capacitance CFD1 are electrically coupled. Furthermore, when the voltage of the FD driving signal FDG_S2 supplied to its gate goes a High level, the switching transistor FDG2 enters a conducting state, whereby the floating diffusion region FD2 and the additional capacitance CFD2 are electrically coupled.

The additional capacitance CFD provides an additional capacitance by coupling with the floating diffusion region FD according to predetermined operating conditions. For example, when the intensity of the received light is high (high illuminance), as described above, the switching transistors FDG1 and FDG2 enter a conducting state due to the FD driving signals FDG_S1 and FDG_S2. As a result, charge overflow in the floating diffusion regions FD1 and FD2 can be prevented and more charges can be stored. Therefore, the dynamic range of the amount of light received by the solid-state imaging apparatus 1 is expanded. Note that the additional capacitances CFD1 and CFD2 are formed by, for example, the capacitance of wiring.

The reset transistor RST is a switching transistor for resetting the potential of the floating diffusion region FD. That is, when the voltage of the FD driving signal RST_S1 supplied to its gate goes a High level, the reset transistor RST1 enters a conducting state, thereby resetting the potential of the floating diffusion region FD1. Furthermore, when the voltage of the FD driving signal RST_S2 supplied to its gate goes a High level, the reset transistor RST2 enters a conducting state, thereby resetting the potential of the floating diffusion region FD2. Note that in this example, in conjunction with the conducting state of the reset transistor RST, the switching transistor FDG also enters a conducting state, and the additional capacitance CFD is reset.

Note that the capacitance CST is a parasitic capacitance due to the provision of the reset transistor RST.

The feedback enable transistor FBEN is a switching transistor that configures a feedback circuit of the feedback amplifier circuit FBOP and controls a reset voltage for the purpose of noise canceling when resetting the charge in the floating diffusion region FD. The floating diffusion region FD1 is formed near the feedback enable transistor FBEN, in this example, on the distal side of the feedback enable transistor FBEN with respect to the photoelectric converter PD.

That is, the feedback enable transistor FBEN1 enters a conducting state when the voltage of the FBEN driving signal FBEN_S1 supplied to its gate goes a High level, whereby the reset transistor RST1 is connected to the feedback amplifier circuit FBOP1. The feedback amplifier circuit FBOP1 operates so that the difference in the differential input between the voltage of the vertical signal line VSL1 and the reference voltage V_{Ref} is eliminated. As a result, the voltage noise (reset noise) of the reset transistor RST1 is canceled out and the charge in the floating diffusion region FD1 can be reliably reset. In addition, the feedback enable transistor FBEN2 enters a conducting state when the voltage of the FBEN driving signal FBEN_S2 supplied to its gate goes a High level, whereby the reset transistor RST2 is connected to the feedback amplifier circuit FBOP2. The feedback amplifier circuit FBOP1 operates so that the difference in the differential input between the voltage of the vertical signal line VSL1 and the reference voltage V_{Ref} is eliminated. As a result, the voltage noise of the reset transistor RST2 is canceled out and the charge in the floating diffusion region FD1 can be reliably reset.

Note that the capacitance CFB is a parasitic capacitance due to the provision of the feedback enable transistor FBEN, and is electrically coupled to the floating diffusion region FD.

The amplification transistor AMP is a transistor that constitutes a source follower circuit. That is, the amplification transistor AMP1 has its source connected to the vertical signal line 19 (VSL1) via the selection transistor SEL1, and further connected to a constant current source (not shown), thereby forming a source follower circuit. Further, the amplification transistor AMP2 has its source connected to the vertical signal line 19 (VSL2) via the selection transistor SEL2, and further connected to a constant current source (not shown), thereby forming a source follower circuit.

The selection transistor SEL is a switching transistor for outputting a pixel signal based on the charge stored in the floating diffusion region FD to the vertical signal line 19 at an arbitrary timing. That is, the selection transistor SEL1 enters a conducting state when the voltage of the selection signal SEL_S1 supplied to its gate goes a High level, whereby the pixel signal based on the charge in the floating diffusion region FD1 is amplified by the amplification transistor AMP1 and output to the vertical signal line VSL1. In addition, the selection transistor SEL2 enters a conducting state when the voltage of the selection signal SEL_S2 supplied to its gate goes a High level, whereby the pixel signal based on the charge in the floating diffusion region FD2 is amplified by the amplification transistor AMP2 and output to the vertical signal line VSL2.

The charge drain transistor OFG is a switching transistor for draining the charge remaining in the photoelectric converter PD. In other words, the charge drain transistor OFG enters a conducting state when the voltage of the charge drain driving signal OFG_S supplied to its gate goes a High level, whereby the potential of the photoelectric converter PD becomes VDD and the charge is drained.

The charge drain transistor OFG may have a vertical structure formed by stacking semiconductor films. Such a transistor is called a vertical transistor. In this way, the charge drain transistor OFG reflects the light leaking from the photoelectric converter PD toward the photoelectric converter PD, thereby promoting the reutilization of light in the photoelectric converter PD, and effectively suppressing light from entering the floating diffusion regions FD1″ and FD2″. Note that, as shown in other embodiments, a plurality of charge drain transistors OFG may be provided in order to promote draining of charges stored in the photoelectric converter PD.

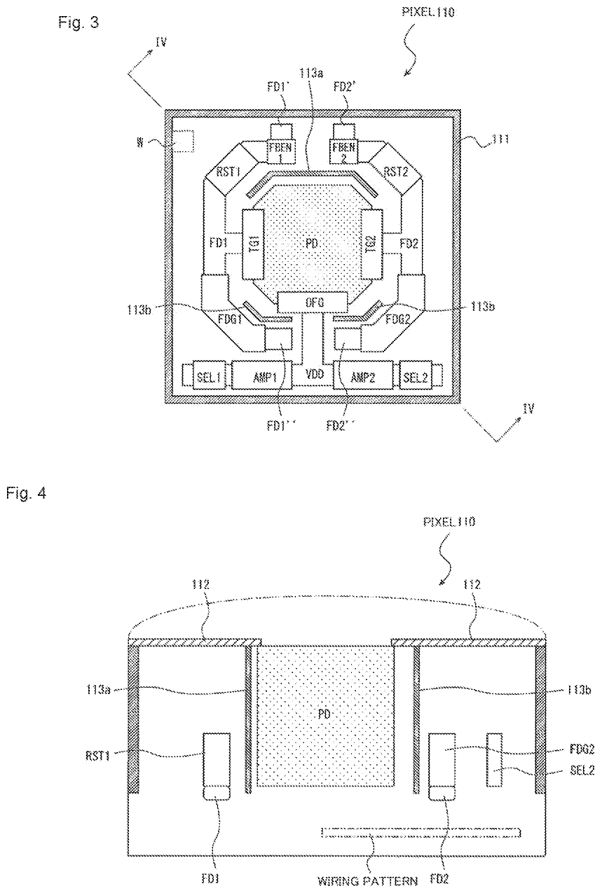

FIG. 3 is a diagram for explaining an example of the planar layout of each element forming a pixel in the pixel array unit of the solid-state imaging apparatus according to the first embodiment of the present technology. This figure shows a planar layout when viewed from the plane (incident plane or light-receiving surface) of the pixel 110 on which light enters. Further, FIG. 4 is a diagram showing an example of a schematic cross-sectional structure of the pixel shown in FIG. 3 along the IV-IV cross-section. Note that in the present disclosure, a plane parallel to the incident plane of the pixel 110 is referred to as an XY plane, and a direction perpendicular to the XY plane is referred to as a Z direction or a depth direction. Hereinafter, each element constituting a pixel will be explained with reference to these figures.

As shown in FIG. 3, the pixel 110 has, for example, a substantially rectangular outer edge shape in plan view (on the XY plane). That is, the pixel 110 includes a semiconductor region defined by the pixel separator 111 into a substantially rectangular shape. The photoelectric converter PD is formed approximately at the center of the pixel 110. In this example, the photoelectric converter PD is formed in an octagonal shape. Note that a well contact W is formed in one corner of the pixel separator 111. The well contact W is preferably formed near the floating diffusion region FD in order to suppress fluctuations in the potential of the floating diffusion region FD.

Further, as shown in FIG. 4, a light-shielding lid 112 is formed on the upper surface (light-receiving surface) of the pixel 110. The light-shielding lid 112 is a structure made of, for example, an oxide insulating film that has a light-shielding property and is provided in front of the pixel to prevent incident light from entering a region other than the photoelectric converter PD, which will be described later. Although not shown, the light-receiving surface of the pixel 110 is provided with an optical element such as a color filter or an on-chip lens.

The pixel separator 111 is a trench-like structure that is provided between adjacent pixels 110 and electrically and optically separates the pixels 110 from each other. Therefore, one side of the pixel 110 is shared with the pixel separator 111 of the adjacent pixel. The pixel separator 111 prevents crosstalk between adjacent pixels 110 and suppresses deterioration in image quality. The pixel separator 111 is formed of an insulating single-layer film or multilayer film, such as silicon oxide (SiO₂), tantalum oxide (Ta₂O₅), hafnium oxide (HfO₂), or aluminum oxide (Al₂O₃). Such an insulating pixel separator 111 is called DTI (Deep Trench Isolation). Alternatively, the pixel separator 111 may be formed of a metal with high light-shielding properties, such as tantalum (Ta), aluminum (Al), silver (Ag), gold (Au), or copper (Cu), and may also be formed of polysilicon.

The various transistors described above are arranged around the photoelectric converter PD. That is, the transfer transistors TG1 and TG2 are formed near a pair of ends of the photoelectric converter PD, respectively, and furthermore, the floating diffusion regions FD1 and FD2 are formed on the outer side of the transfer transistors TG1 and TG2. In this example, the floating diffusion regions FD1 and FD2 are formed along the periphery of the photoelectric converter PD so as to partially surround the photoelectric converter PD. Further, near the other end of the photoelectric converter PD, a power supply wiring pattern VDD formed in the wiring layer and a charge drain transistor OFG electrically connected to the power supply wiring pattern VDD are formed. The wiring layer can contribute to the reutilization of light in the photoelectric converter PD by reflecting light leaking from the photoelectric converter PD. Further, in the figure, the amplification transistors AMP1 and AMP2 and the selection transistors SEL1 and SEL2 are formed so as to overlap the extending power supply wiring pattern VDD in the Z direction. Note that in this example, the feedback amplifier circuit FBOP is not shown in the figure because it is formed at a separate position through the wiring layer.

Further, around the photoelectric converter PD, the reset transistors RST1 and RST2, the feedback enable transistors FBEN1 and FBEN2, and the switching transistors FDG1 and FDG2 are formed so as to overlap the floating diffusion regions FD1 and FD2 in the Z direction. In this example, the floating diffusion regions FD1′ and FD2′ and FD1″ and FD2″ are formed to extend near the feedback enable transistors FBEN1 and FBEN2 and the switching transistors FDG1 and FDG2, respectively. That is, in this example, the floating diffusion region FD′ is formed on the distal side of the feedback enable transistors FBEN1 and FBEN2 with respect to the photoelectric converter PD, and the floating diffusion region FD″ is formed between a pair of switching transistors FDG1 and FDG2.

Further, the switching transistor FDG of this example is a vertical transistor having a vertical structure in which semiconductor films are stacked in the Z direction (see FIG. 4). Furthermore, the switching transistor FDG is configured to have a bent portion along the outer periphery of the photoelectric converter PD in plan view. In this way, the switching transistor FDG reflects the light leaking from the photoelectric converter PD (some of which may include reflected light from the wiring layer) toward the photoelectric converter PD, thereby effectively suppressing the entry of light into the floating diffusion region FD1″ and FD2″ and promoting the reutilization of light in the photoelectric converter PD.

A shielding portion 113a is provided between the photoelectric converter PD and the feedback enable transistors FBEN1 and FBEN2. The shielding portion 113a is, for example, a trench-shaped structure that blocks or reflects light leaking from the photoelectric converter PD and directed toward the floating diffusion regions FD1′ and FD2′ formed near the feedback enable transistors FBEN1 and FBEN2. In this example, the shielding portion 113a is formed along the outer periphery of the photoelectric converter PD. Furthermore, the shielding portion 113a extends deep in the Z direction so that it can effectively block or reflect light directed toward the floating diffusion regions FD1′ and FD2′. The light reflected by the shielding portion 113a enters the photoelectric converter PD and reutilized, thereby contributing to the generation of charges. Additionally, the feedback enable transistor FBEN may be a vertical transistor. In this way, light leaking from the photoelectric converter PD and directed toward the floating diffusion regions FD1′ and FD2′ can be reliably blocked.

Furthermore, a shielding portion 113b is provided between the photoelectric converter PD and the switching transistors FDG1 and FDG2. The shielding portion 113b is, for example, a trench-shaped structure that blocks or reflects light leaking from the photoelectric converter PD and directed toward the floating diffusion regions FD1″ and FD2″ formed near the switching transistors FDG1 and FDG2. In this example, the shielding portion 113b is formed along the outer periphery of the photoelectric converter PD. The shielding portion 113b also extends deep in the Z direction so that it can effectively block or reflect light directed toward the floating diffusion regions FD1″ and FD2″. The light reflected by the shielding portion 113b enters the photoelectric converter PD and reutilized, thereby contributing to the generation of charges.

The shielding portion 113 is made of an insulating single layer or multilayer film of silicon oxide (SiO₂), tantalum oxide (Ta₂O₅), hafnium oxide (HfO₂), or aluminum oxide (Al₂O₃), for example, like the pixel separator 111 described above, but there is no limitation thereto. For example, the shielding portion 113a may be formed of metal having high light-shielding properties, such as tantalum (Ta), aluminum (Al), silver (Ag), gold (Au), or copper (Cu), and may be formed of polysilicon (Polycrystalline Silicon). In this example, the shielding portion 113 has a bent portion formed along the outer periphery of the photoelectric converter PD. Note that the shape and arrangement of the shielding portion 113 can take various forms, as will be described later.

As described above, according to the present embodiment, it is possible to reliably suppress unintended light from entering the floating diffusion region FD in the pixel 110. In particular, in the pixel 110 adapted to the indirect ToF method, since the shielding portion 113a is provided between the photoelectric converter PD and the feedback enable transistor FBEN, it is possible to reflect light leaking from the photoelectric converter PD toward the photoelectric converter PD and reliably suppress the entry of light into the floating diffusion region FD′ formed near the feedback enable transistor FBEN, thereby promoting the reutilization of light in the photoelectric converter PD. Furthermore, in the present embodiment, since the shielding portion 113b is provided between the photoelectric converter PD and the switching transistor FDG, similarly, it is possible to reflect the light leaking from the photoelectric converter PD toward the photoelectric converter PD, and reliably suppress the entry of light into the floating diffusion region FD″ formed near the switching transistor FDG, thereby promoting the reutilization of light in the photoelectric converter PD.

### (Modification 1-1)

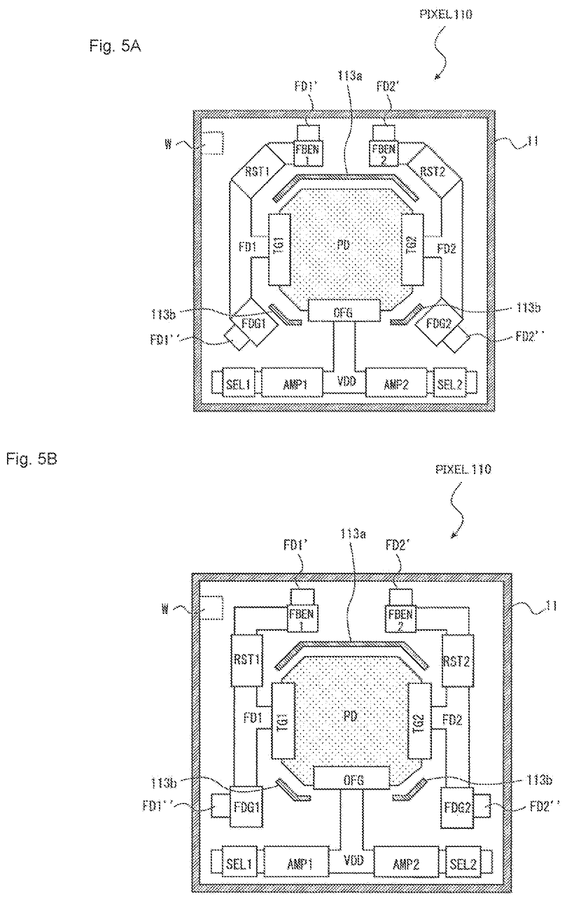

FIG. 5A is a diagram for explaining another example of the planar layout of each element forming a pixel in the pixel array unit of the solid-state imaging apparatus according to the first embodiment of the present technology. In this example, the shape of the switching transistor FDG is different, and the floating diffusion region FD″ near it is formed at a different position.

As shown in the figure, the switching transistors FDG1 and FDG2 are formed into a substantially rectangular shape in plan view. That is, the switching transistors FDG1 and FDG2 of this example do not have bent portions unlike the above-mentioned example. Note that the switching transistors FDG1 and FDG2 are preferably formed as vertical transistors.

The floating diffusion regions FD1″ and FD2″ near the switching transistors FDG1 and FDG2 are formed on the distal side with respect to the photoelectric converter PD. That is, the floating diffusion regions FD1″ and FD2″ are formed behind the switching transistors FDG1 and FDG2, which are formed obliquely with respect to the pixel separator 111 in plan view. Moreover, the shielding portions 113b1 and 113b2 are formed in the portions where the switching transistors FDG1 and FDG2 substantially face the photoelectric converter PD.

Also in the pixel 110 having the above configuration, it is possible to reliably suppress unintended light from entering the floating diffusion region FD in the pixel 110, similarly to the above-described example. In particular, in this example, since the floating diffusion region FD″ formed near the switching transistor FDG is formed on the distal side of the switching transistor FDG with respect to the photoelectric converter PD, it is possible to reliably suppress the entry of light into the floating diffusion region FD″ due to the switching transistor FDG and further widen the light-receiving region of the photoelectric converter PD. Further, when the switching transistor FDG is formed as a vertical transistor, it becomes possible to more effectively and reliably suppress the entry of light.

### (Modification 1-2)

FIG. 5B is a diagram for explaining still another example of the planar layout of each element forming a pixel in the pixel array unit of the solid-state imaging apparatus according to the first embodiment of the present technology. This example is a further modification of the above-described modification 1-2, in which the floating diffusion region FD″ near the switching transistor FDG is formed at another different position.

That is, as shown in the figure, the switching transistor FDG of this example is provided substantially parallel to the pixel separator 111 in plan view. Further, the floating diffusion region FD″ near the switching transistor FDG is formed to face the pixel separator 111. In other words, the floating diffusion region FD″ is formed further away from the photoelectric converter PD.

Also in the pixel 110 having the above configuration, it is possible to reliably suppress unintended light from entering the floating diffusion region FD in the pixel 110, similarly to the above-described example. In particular, in this example, since the floating diffusion region FD″ formed near the switching transistor FDG is provided on a distal side of the switching transistor FDG with respect to the photoelectric converter PD so as to face the pixel separator 111, the floating diffusion region FD″ can be further separated from the photoelectric converter PD. Thus, it is possible to reliably suppress the entry of light into the floating diffusion region FD″ due to the switching transistor FDG and further widen the light-receiving region of the photoelectric converter PD.

### 2. Second Embodiment

The present embodiment is a modification of the first embodiment, and is characterized by being a solid-state imaging apparatus including a pixel having a structure in which two charge drain transistors are arranged around the photoelectric converter PD.

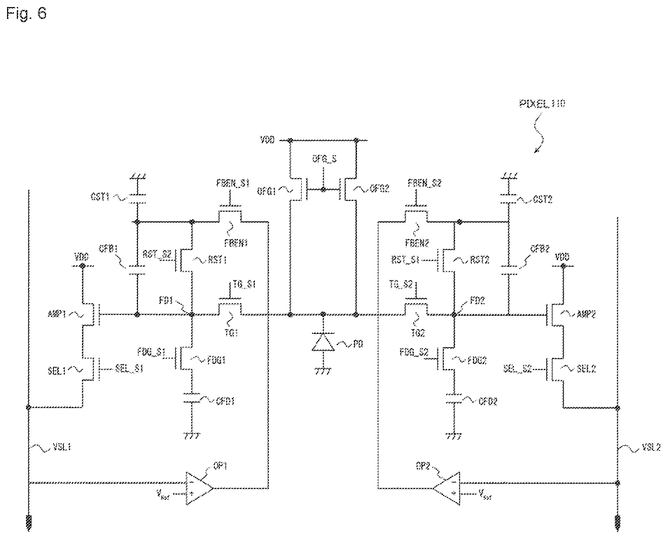

FIG. 6 is a diagram illustrating an example of a circuit configuration of pixels in a pixel array unit of the solid-state imaging apparatus according to the second embodiment of the present technology. That is, the figure shows an example of the circuit configuration of any one pixel (unit pixel) 110 among the plurality of pixels 110 that constitute the pixel array unit 11 of the solid-state imaging apparatus 1 shown in FIG. 1.

That is, as shown in the figure, in the pixel 110 of the present embodiment, the charge drain transistors OFG1 and OFD2 for draining the charges stored in the photoelectric converter PD are connected to the photoelectric converter PD. The charge drain transistors OFG1 and OFD2 can be formed as vertical transistors. The charge drain transistors OFG1 and OFD2 may be the same, or may be different in size (for example, the thickness of the gate insulating film). The charge drain transistors OFG1 and OFD2 enter a conducting state when the voltage of the common drain driving signal OFG_S supplied to their gates goes a High level, whereby the potential of the photoelectric converter PD becomes VDD and the charge is drained. In this way, in the present embodiment, since the two charge drain transistors OFG1 and OFD2 are provided, the potential of the photoelectric converter PD can be reset more quickly.

Note that in the figure, other transistors such as the transfer transistor TG are the same as those in the first embodiment, and therefore, their descriptions will be omitted.

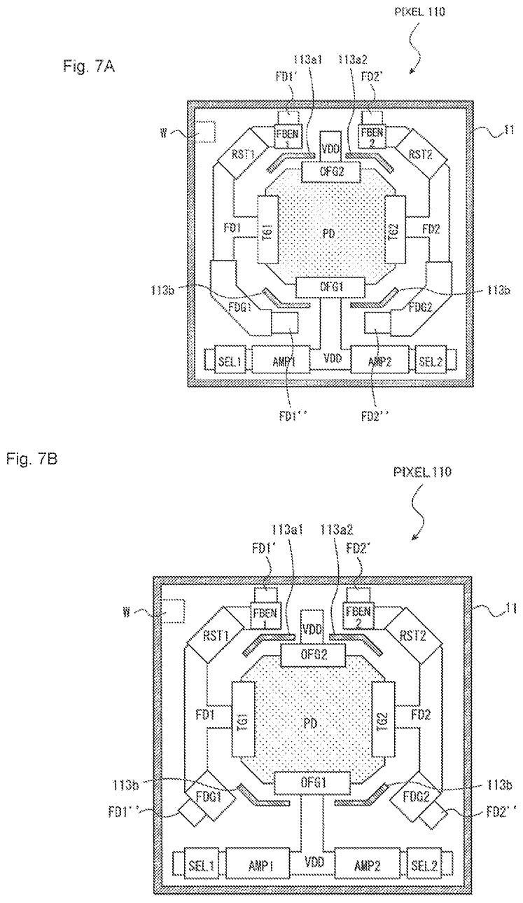

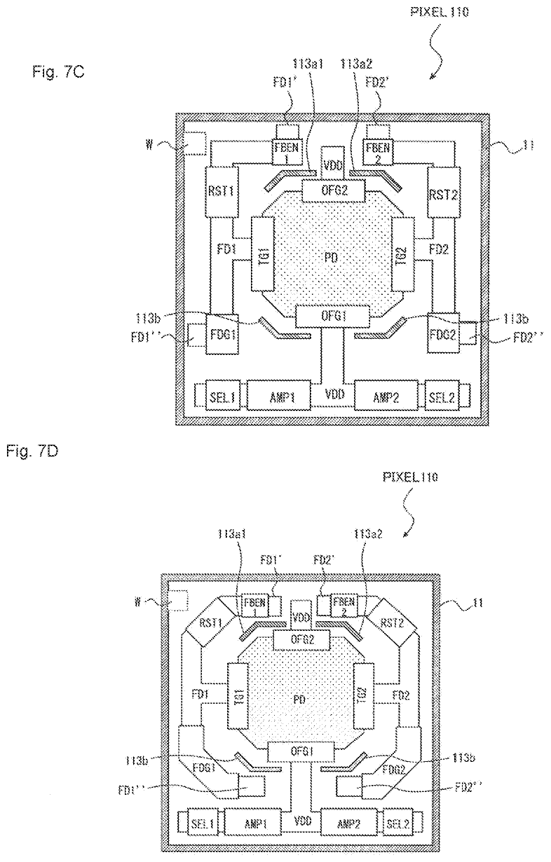

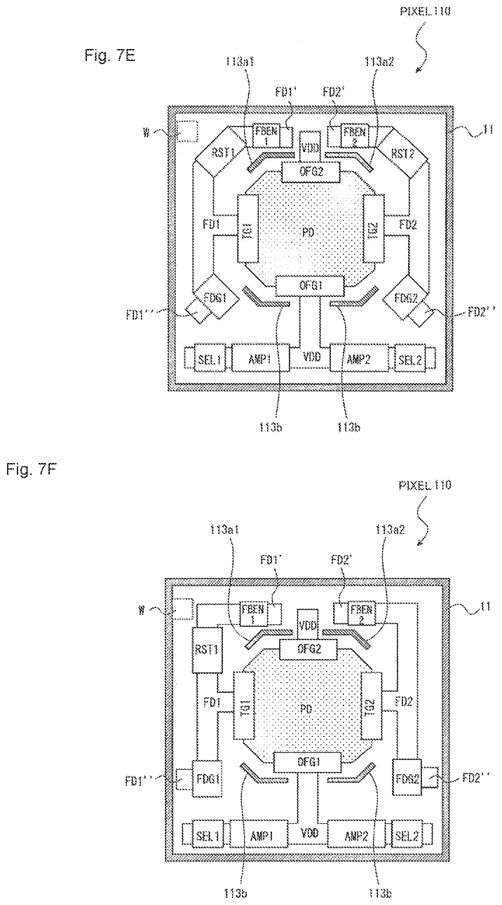

FIG. 7A is a diagram for explaining an example of a planar layout of each element forming a pixel in the pixel array unit of the solid-state imaging apparatus according to the second embodiment of the present technology. As shown in the figure, in this example, in the pixel 110, the transfer transistors TG1 and TG2 are formed near a pair of one set of ends of the photoelectric converter PD, and the charge drain transistors OFG1 and OFD2 are formed near another pair of the other ends different from the pair of one set of ends. That is, the charge drain transistor OFD2 is formed near the feedback enable transistor FBEN. Further, in this example, the VDD wiring pattern extends in the wiring layer to almost directly below the charge drain transistor OFD2, and electrically connects the charge drain transistor OFD2.

Furthermore, in this example, shielding portions 113a1 and 113a2 are provided to block light leaking from the photoelectric converter PD and directed toward the floating diffusion regions FD′ near the feedback enable transistors FBEN1 and FBEN2. As another example, similarly to the above-described embodiment, the shielding portions 113a1 and 113a2 may be configured as one continuous shielding portion 113a.

As described above, according to the present embodiment, the same advantages and effects as the first embodiment can be achieved. In particular, according to the present embodiment, since the charge drain transistor OFG2 formed as a vertical transistor is disposed near the feedback enable transistor FEBN, light leaking from the photoelectric converter PD can be reflected toward the photoelectric converter PD. As a result, it is possible to promote the reutilization of light in the photoelectric converter PD and effectively suppress the entry of light into the floating diffusion region FD.

### (Modification 2-1)

FIG. 7B is a diagram for explaining another example of the planar layout of each element forming a pixel in the pixel array unit of the solid-state imaging apparatus according to the second embodiment of the present technology. In this example, two charge drain transistors OFG are provided, and the switching transistor FDG is formed in a structure that does not have a bent portion, similarly to the above-described modification 1-1.

First, as shown in the figure, the switching transistors FDG1 and FDG2 are formed into a substantially rectangular shape in plan view. That is, the switching transistors FDG1 and FDG2 of this example do not have bent portions unlike the above-mentioned example. Note that in this example, the switching transistors FDG1 and FDG2 are preferably formed as vertical transistors.

The floating diffusion regions FD1″ and FD2″ near the switching transistors FDG1 and FDG2 are formed on the distal side with respect to the photoelectric converter PD. In other words, the floating diffusion regions FD1″ and FD2″ are formed behind the switching transistors FDG1 and FDG2 and obliquely with respect to the pixel separator 111 in plan view. Moreover, the shielding portions 113b1 and 131b2 are formed in the portions where the switching transistors FDG1 and FDG2 substantially face the photoelectric converter PD.

Also in the pixel 110 having the above configuration, it is possible to reliably suppress unintended light from entering the floating diffusion region FD in the pixel 110, similarly to the above-described example. In particular, in this example, since the floating diffusion region FD″ formed near the switching transistor FDG is formed on the distal side of the switching transistor FDG with respect to the photoelectric converter PD, it is possible to reliably suppress the entry of light into the floating diffusion region FD″ due to the switching transistor FDG and further widen the light-receiving region of the photoelectric converter PD. Further, when the switching transistor FDG is formed as a vertical transistor, it becomes possible to more effectively and reliably suppress the entry of light.

### (Modification 2-2)

FIG. 7C is a diagram for explaining still another example of the planar layout of each element forming a pixel in the pixel array unit of the solid-state imaging apparatus according to the second embodiment of the present technology. This example is a further modification of the above-described modification 1-2, in which the floating diffusion region FD″ near the switching transistor FDG is formed at a position further away from the photoelectric converter PD.

That is, as shown in the figure, the switching transistor FDG of this example is provided substantially parallel to the pixel separator 111 in plan view. Further, the floating diffusion region FD″ near the switching transistor FDG is provided so as to face the pixel separator 111. Therefore, the floating diffusion region FD″ is formed further away from the photoelectric converter PD.

Also in the pixel 110 having the above configuration, it is possible to reliably suppress unintended light from entering the floating diffusion region FD in the pixel 110, similarly to the above-described example. In particular, in this example, since the floating diffusion region FD″ formed near the switching transistor FDG is provided on the distal side of the switching transistor FDG with respect to the photoelectric converter PD so as to face the pixel separator 111, the floating diffusion region FD″ can be further separated from the photoelectric converter PD. Thus, it is possible to reliably suppress the entry of light into the floating diffusion region FD″ due to the switching transistor FDG and further widen the light-receiving region of the photoelectric converter PD.

### (Modification 2-3)

FIG. 7D is a diagram for explaining still another example of the planar layout of each element forming a pixel in the pixel array unit of the solid-state imaging apparatus according to the second embodiment of the present technology. In this example, the floating diffusion region FD′ is formed between the feedback enable transistors FBEN.

That is, as shown in the figure, the floating diffusion regions FD′ of this example are formed so as to face each other along one end of the photoelectric converter PD between the feedback enable transistors FBEN1 and FBEN2 in plan view. That is, the floating diffusion region FD′ is formed between a pair of feedback enable transistors FBEN1 and FBEN2. As a result, the transistors in the pixel 110 can be arranged more efficiently. Furthermore, in this example, although the floating diffusion region FD′ is formed at a position closer to one end of the photoelectric converter PD than in the above-mentioned example, it is possible to suppress the entry of light due to the shielding portions 113a1 and 131a2 and the charge drain transistor OFG2 and further widen the light-receiving region of the photoelectric converter PD.

### (Modification 2-4)

FIG. 7E is a diagram for explaining still another example of the planar layout of each element forming a pixel in the pixel array unit of the solid-state imaging apparatus according to the second embodiment of the present technology. In this example, the floating diffusion region FD″ near the switching transistor FDG is formed at a different position.

That is, the floating diffusion regions FD1″ and FD2″ near the switching transistors FDG1 and FDG2 are formed behind the switching transistors FDG1 and FDG2, which are formed obliquely with respect to the pixel separator 111 in plan view. Moreover, the shielding portions 113b1 and 131b2 are formed in the portions where the switching transistors FDG1 and FDG2 substantially face the photoelectric converter PD.

Also in the pixel 110 having the above configuration, it is possible to reliably suppress unintended light from entering the floating diffusion region FD in the pixel 110, similarly to the above-described example. In particular, in this example, since the floating diffusion region FD″ formed near the switching transistor FDG is formed on the distal side of the switching transistor FDG with respect to the photoelectric converter PD, it is possible to reliably suppress the entry of light into the floating diffusion region FD″ due to the switching transistor FDG and further widen the light-receiving region of the photoelectric converter PD.

### (Modification 2-5)

FIG. 7F is a diagram for explaining still another example of the planar layout of each element forming a pixel in the pixel array unit of the solid-state imaging apparatus according to the first embodiment of the present technology. In this example, the floating diffusion region FD″ near the switching transistor FDG is formed at a different position.

That is, as shown in the figure, the switching transistor FDG of this example is provided substantially parallel to the pixel separator 111 in plan view. Further, the floating diffusion region FD″ near the switching transistor FDG is formed to face the pixel separator 111. Therefore, the floating diffusion region FD″ is formed further away from the photoelectric converter PD.

Also in the pixel 110 having the above configuration, it is possible to reliably suppress unintended light from entering the floating diffusion region FD in the pixel 110, similarly to the above-described example. In particular, in this example, since the floating diffusion region FD″ formed near the switching transistor FDG is provided on a distal side of the switching transistor FDG with respect to the photoelectric converter PD so as to face the pixel separator 111, the floating diffusion region FD″ can be further separated from the photoelectric converter PD. Thus, it is possible to reliably suppress the entry of light into the floating diffusion region FD″ due to the switching transistor FDG and further widen the light-receiving region of the photoelectric converter PD.

### 3. Third Embodiment

The present embodiment is a modification of the above-described embodiment, and is characterized in that the amplification transistor AMP and the selection transistor SEL constituting the source follower circuit are formed at different positions.

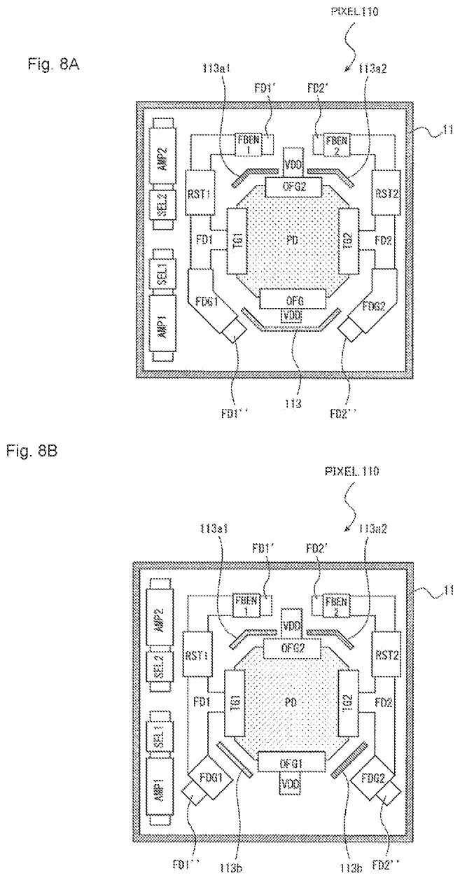

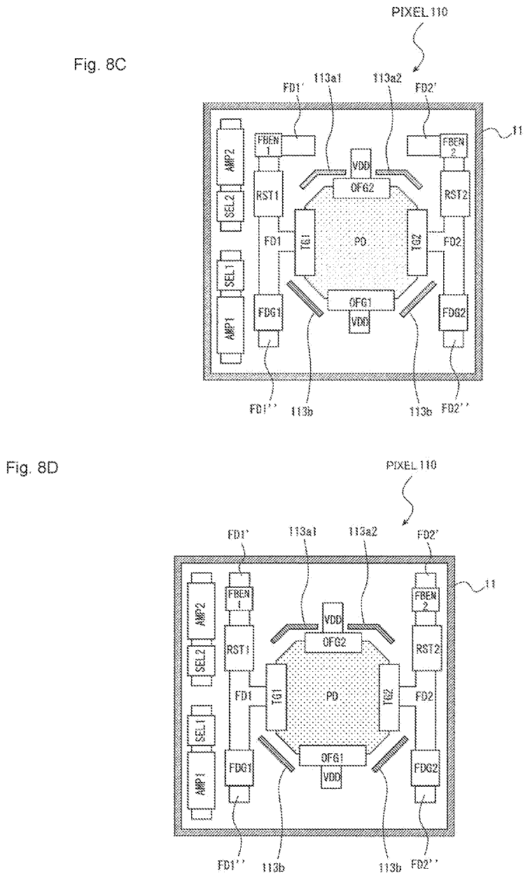

FIG. 8A is a diagram for explaining an example of a planar layout of each element forming a pixel in a pixel array unit of the solid-state imaging apparatus according to the third embodiment of the present technology.

That is, as shown in the figure, the amplification transistor AMP and the selection transistor SEL are provided parallel to one side of the pixel separator 111 orthogonal to the line connecting the transfer transistors TG1 and TG2. Therefore, since the distance between the transfer transistors TG1 and TG2 is narrowed, the electric field of the photoelectric converter PD is increased, and the charge distribution ability is improved.

In such an arrangement, in one pixel 110, the wiring distance between the transfer transistor TG2 and the amplification transistor AMP2 and the selection transistor SEL2 increases. Therefore, the amplification transistor AMP2 and the selection transistor SEL2 in the other pixel 110 located on the transfer transistor TG2 side are configured to read out the floating diffusion region FD2 that stores the charge transferred from the transfer transistor TG2 in the one pixel 110.

### (Modification)

FIGS. 8B to 8D are diagrams for explaining other examples of the planar layout of each element forming a pixel in the pixel array unit of the solid-state imaging apparatus according to the third embodiment of the present technology. The examples shown in these figures correspond to the various planar layouts described above, and have similar advantages and effects, so the explanation will be omitted.

Also in the pixel 110 having the above configuration, it is possible to reliably suppress unintended light from entering the floating diffusion region FD in the pixel 110, similarly to the above-described example. In particular, in this example, since the distance between the transfer transistors TG1 and TG2 provided at a pair of ends of the photoelectric converter PD is shortened, the electric field of the photoelectric converter PD is increased, and the charge distribution ability is improved.

### 4. Fourth Embodiment

The present embodiment is a modification of the above-described embodiment, and is characterized in that some transistors in the pixel are configured as vertical transistors. As explained below, the structure of the vertical transistor is appropriately determined in consideration of light-shielding properties and charge transfer efficiency.

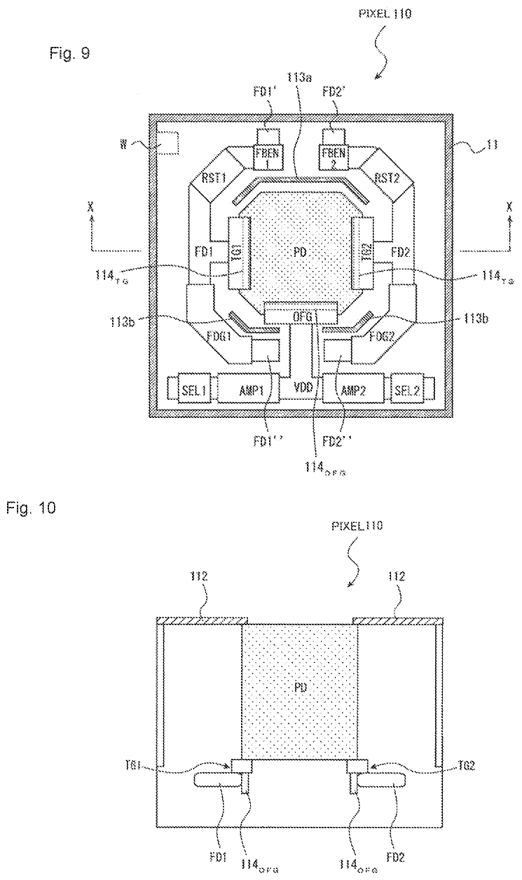

FIG. 9 is a diagram for explaining an example of a planar layout of each element forming a pixel in a pixel array unit of the solid-state imaging apparatus according to the fourth embodiment of the present technology. Further, FIG. 10 is a diagram showing an example of a schematic cross-sectional structure of the pixel shown in FIG. 9 along the X-X cross-section.

As shown in these figures, in the pixel 110 of the present embodiment, the transfer transistor TG and the charge drain transistor OFG are formed as vertical transistors having an embedded structure 114 in a portion thereof. Further, although not shown, a gate oxide film is formed under the embedded structure 114.

The embedded structure 114_{TG} of the transfer transistor TG reflects or blocks light leaking from the photoelectric converter PD and directed toward the floating diffusion region FD. The light reflected by the embedded structure 114_{TG} enters the photoelectric converter PD and is reutilized. When the transfer driving signal TG_S supplied to its gate goes a High level, the transfer transistor TG transfers the charge generated by the photoelectric converter PD to the floating diffusion region FD. At this time, since the charge in the photoelectric converter PD is transferred to the floating diffusion region FD through the silicon layer under the embedded structure 114_{TG}, the flow is slightly suppressed and the charge transfer efficiency decreases. However, since light leaking from the photoelectric converter PD and directed toward the floating diffusion region FD is effectively reflected or blocked, deterioration in image quality can be prevented.

Similarly, the embedded structure 114_{OFG} of the charge drain transistor OFG reflects or blocks light directed toward the floating diffusion region FD″ near the switching transistor FDG. The light reflected by the embedded structure 114_{OFG} enters the photoelectric converter PD and is reutilized. The charge drain transistor OFG drains the potential of the photoelectric converter PD when the charge drain driving signal OFG_S supplied to its gate goes a High level.

As described above, since the transfer transistor TG and the charge drain transistor OFG of this example are formed as vertical transistors, it is possible to reliably suppress light from entering the floating diffusion region FD and allow the light to be incident again on the photoelectric converter PD and be reutilized.

### (Modification 4-1)

The embedded structure 114 of the transfer transistor TG and/or the charge drain transistor OFG can take various forms in consideration of light-shielding properties and charge transfer efficiency.

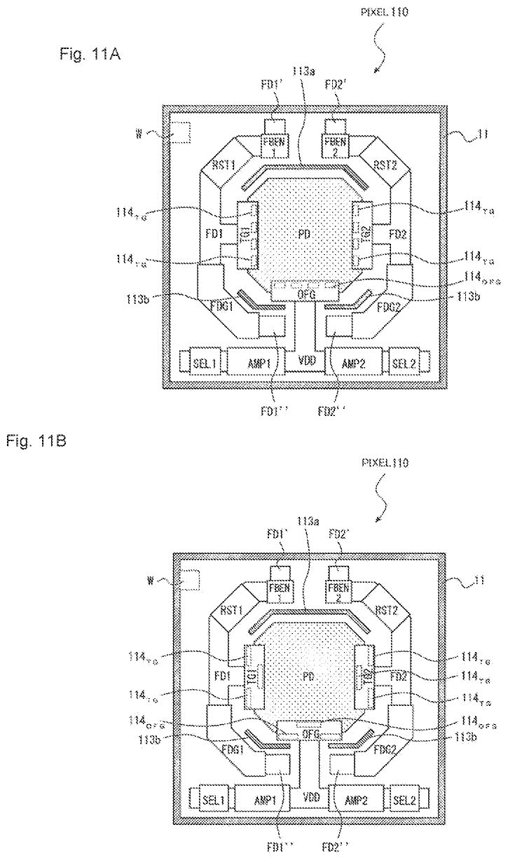

FIG. 11A is a diagram for explaining another example of the planar layout of each element forming a pixel in the pixel array unit of the solid-state imaging apparatus according to the fourth embodiment of the present technology. As shown in the figure, the embedded structure 114 of the transfer transistor TG and the charge drain transistor OFG is formed in a so-called comb shape or column shape (indicated by a small square dotted line in the figure). In other words, the embedded structure 114 of this example partially has gaps in the Z direction (depth direction). Since such a comb-shaped embedded structure 114 allows charges to pass through the gap, it is possible to prevent excessive reduction in charge transfer efficiency while taking light-shielding properties into consideration.

On the other hand, FIG. 11B is a diagram for explaining still another example of the planar layout of each element forming a pixel in the pixel array unit of the solid-state imaging apparatus according to the fourth embodiment of the present technology. As shown in the figure, the embedded structure 114 of the transfer transistor TG and the charge drain transistor OFG is formed in a zigzag shape in plan view. Since the embedded structure 114 of this example has fewer gaps than the comb-shaped embedded structure 114 of FIG. 11A, the balance between light-shielding properties and charge transfer efficiency can be adjusted as appropriate.

### (Modification 4-2)

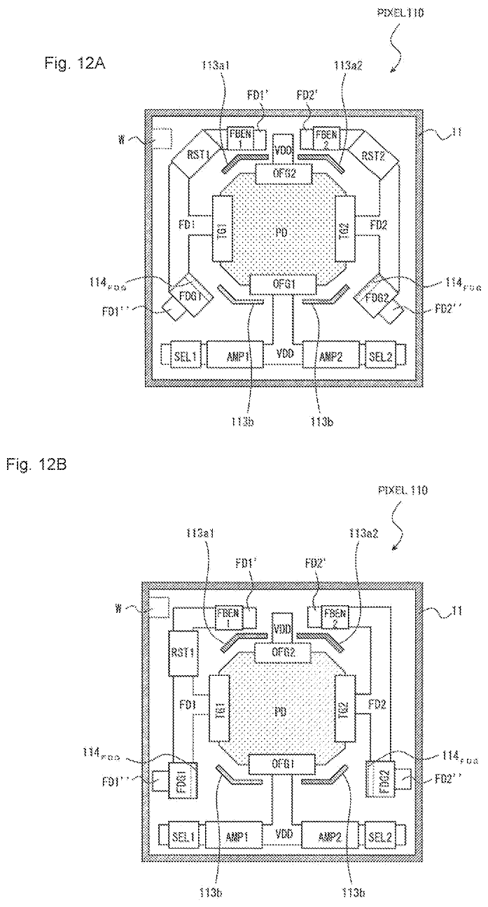

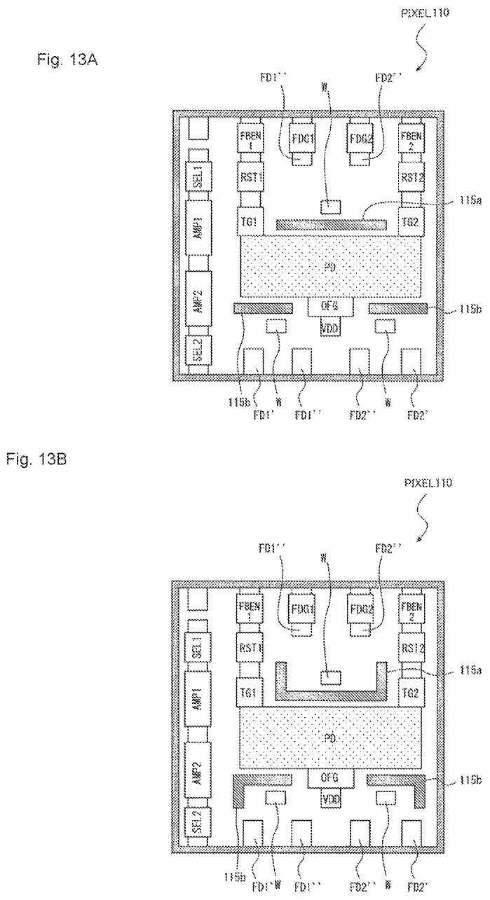

FIGS. 12A and 12B are diagrams for explaining still other examples of the planar layout of each element forming a pixel in the pixel array unit of the solid-state imaging apparatus according to the fourth embodiment of the present technology. As shown in these figures, the vertical transistor can be applied not only to the transfer transistor TG and/or the charge drain transistor OFG, but also, for example, to the switching transistor FDG. That is, the switching transistor FDG of this example is configured as a vertical transistor having an embedded structure 114_{FDG} in a portion thereof.

### 5. Fifth Embodiment

The present embodiment is a modification of the above-described embodiment, and is characterized in that the shielding portion 113 is formed by a dummy transistor with a vertical structure. The dummy transistor is a transistor that has a semiconductor stacked structure and is not electrically connected to any wiring pattern.

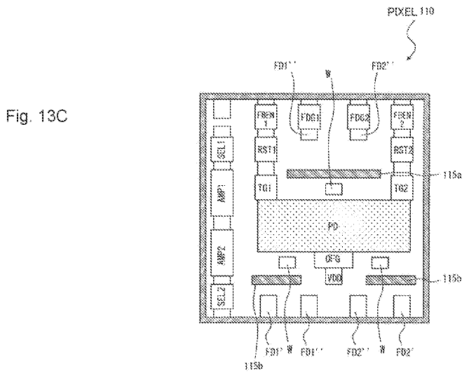

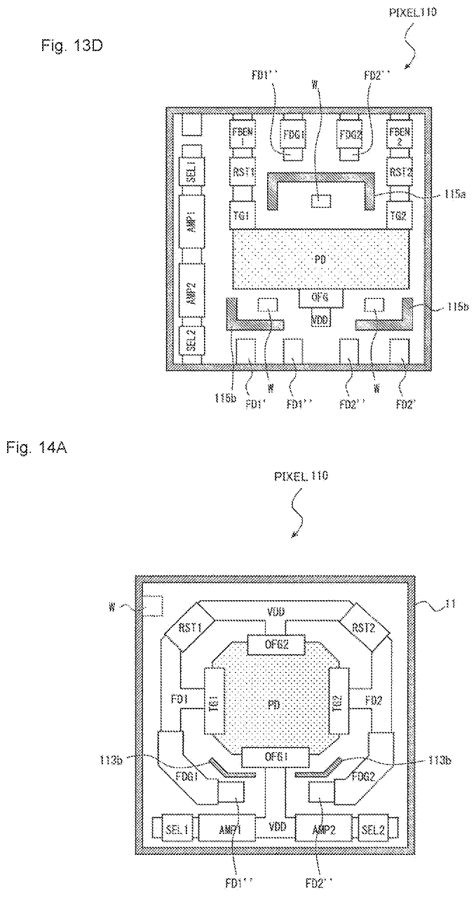

FIGS. 13A to 13D are diagrams for explaining an example of a planar layout of each element forming a pixel in a pixel array unit of the solid-state imaging apparatus according to the fifth embodiment of the present technology, respectively.

That is, as shown in FIG. 13A, a dummy transistor 115a is formed between the transfer transistors TG1 and TG2 along one end of the photoelectric converter PD. In this way, light leaking from the photoelectric converter PD can be suppressed from entering the floating diffusion region FD near the transfer transistor TG and the floating diffusion region FD″ near the switching transistor FDG.

Furthermore, dummy transistors 115b1 and 115b2 are formed on both sides of the charge drain transistor OFG. That is, the dummy transistors 115b1 and 115b2 are formed along one end of the photoelectric converter PD so as to suppress the entry of light into the floating diffusion regions FD1′ and FD2′ near the feedback enable transistors FBEN1 and FBEN2, and the floating diffusion regions FD1″ and FD2″ near the switching transistors FDG1 and FDG2, the floating diffusion regions extending from an adjacent pixel 110.

In addition, in this example, a well contact W for electrically connecting to a semiconductor conductive region (well) is formed on the distal side of the dummy transistors 115a and 115b with respect to the photoelectric converter PD, that is, near the floating diffusion regions FD, FD′, and FD″. In this way, it is possible to reduce potential fluctuations in the floating diffusion regions FD, FD′, and FD″.

FIG. 13B shows an example in which the dummy transistors 115a and 115b each have a bent portion. In this way, entry of light can be further suppressed.

FIGS. 13C and 13D show an example in which the well contact W is disposed near the photoelectric converter PD. In this way, the dummy transistors 115a and 115b can be placed closer to the floating diffusion regions FD, FD′, and FD″, and the entry of light can be further suppressed.

### 6. Sixth Embodiment

The present embodiment shows an example of a pixel in which the feedback enable transistor FBEN is omitted.

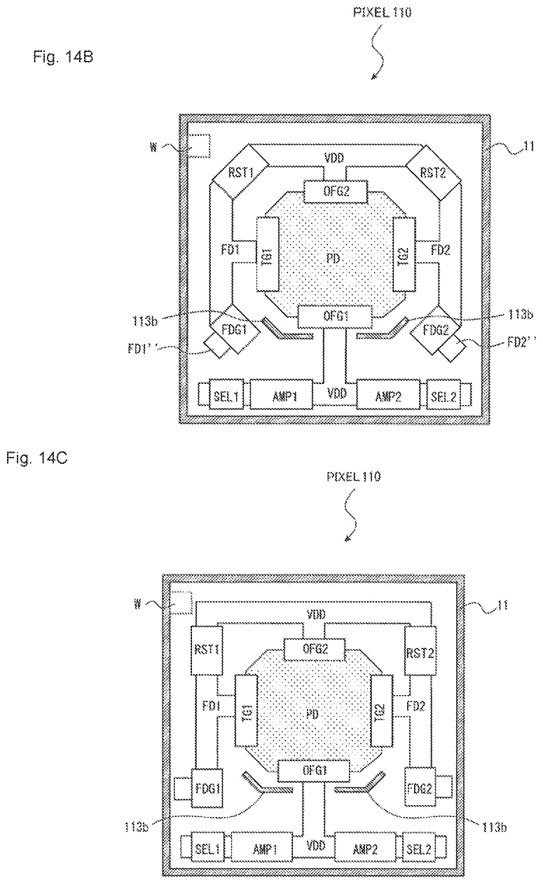

FIGS. 14A to 14C are diagrams for explaining an example of a planar layout of each element forming a pixel in a pixel array unit of a solid-state imaging apparatus according to the fifth embodiment of the present technology, respectively. As shown in these figures, the pixel 110 of the present embodiment differs from the above-described embodiments in that the feedback enable transistor FBEN is omitted. Furthermore, this example shows an example using two charge drain transistors OFG.

As described above, the present technology can be applied to various pixels 110 in which the feedback enable transistor FBEN is omitted.

Each of the aforementioned embodiments is an illustrative example for explaining the present technology, and the present technology is not intended to be limited only to these embodiments. The present technology can be implemented in various forms without departing from the gist thereof.

For example, the steps, the operations, or the functions of the method disclosed in the specification may be performed in parallel or in a different order unless conflicts occur in the result thereof. The described steps, operations, and functions are provided as merely examples, and some of the steps, operations, and functions may be omitted or combined in one step, operation, and functions without departing from the scope and spirit of the invention, and other steps, operations, or functions may be added.

Also, although various embodiments have been disclosed in the specification, specific features (technical matters) in one of the embodiments may be added to a different embodiment with appropriate improvements or may be replaced with a specific feature in the different embodiment, and such an embodiment is also included within the gist of the present technology.

Also, the present technology may be configured to include the following technical matters.

(1)

A solid-state imaging apparatus including a pixel array unit in which a plurality of pixels are arranged in an array, wherein
each of the plurality of pixels includes:
a pixel separator that defines an outer edge shape of the pixel and is formed between the adjacent pixels;
a photoelectric converter that generates an amount of charge corresponding to light incident from the outside;
a plurality of transistors, including a transfer transistor formed at one end of the photoelectric converter to transfer the charge generated by the photoelectric converter;
a floating diffusion region formed around the photoelectric converter to temporarily store the charges generated and transferred by the photoelectric converter; and
a shielding portion formed around the photoelectric converter to block light leaking from the photoelectric converter and directed toward the floating diffusion region, the plurality of transistors further includes:
a reset transistor for resetting a potential of the floating diffusion region; and
a feedback enable transistor connected to a feedback amplifier circuit for canceling out voltage noise of the reset transistor, and
the shielding portion includes a first shielding portion that blocks light directed toward a portion of the floating diffusion region formed near the feedback enable transistor.
   (2)

The solid-state imaging apparatus according to (1), wherein
the shielding portion is formed to reflect light leaking from the photoelectric converter toward the photoelectric converter.
   (3)

The solid-state imaging apparatus according to (1) or (2), wherein
the shielding portion has a bent portion formed along an outer peripheral edge of the photoelectric converter.
   (4)

The solid-state imaging apparatus according to any one of (1) to (3), wherein the portion of the floating diffusion region formed near the feedback enable transistor is formed on a distal side of the feedback enable transistor with respect to the photoelectric converter.

(5)

The solid-state imaging apparatus according to any one of (1) to (4), wherein the feedback enable transistor is configured as a vertical transistor made of polycrystalline silicon.

(6)

The solid-state imaging apparatus according to any one of (1) to (5), wherein the portion of the floating diffusion region formed near the feedback enable transistor is formed between a pair of the feedback enable transistors.

(7)

The solid-state imaging apparatus according to any one of (1) to (6), wherein
the plurality of transistors further includes a switching transistor formed around the photoelectric converter to electrically couple the floating diffusion region to an additional capacitance, and
the shielding portion further includes a second shielding portion that blocks light directed toward another portion of the floating diffusion region formed near the switching transistor.
   (8)

The solid-state imaging apparatus according to any one of (1) to (7), wherein the switching transistor is formed to have a bent portion.

(9)

The solid-state imaging apparatus according to (7), wherein
the switching transistor is configured as a vertical transistor made of polycrystalline silicon.
   (10)

The solid-state imaging apparatus according to any one of (7) to (9), wherein the other portion of the floating diffusion region formed near the switching transistor is formed to face between a pair of switching transistors.

(11)

The solid-state imaging apparatus according to any one of (7) to (9), wherein the other portion of the floating diffusion region formed near the switching transistor is formed on a distal side of the switching transistor with respect to the photoelectric converter.

(12)

The solid-state imaging apparatus according to any one of (1) to (11), wherein
the plurality of transistors further includes at least one charge drain transistor formed at the other end of the photoelectric converter different from the one end to drain charges remaining in the photoelectric converter.
   (13)

The solid-state imaging apparatus according to (12), wherein
the charge drain transistor is configured as a vertical transistor made of polycrystalline silicon.
   (14)

The solid-state imaging apparatus according to (13), wherein
a vertical structure of the charge drain transistor partially has a gap in a surface in a depth direction of the pixel.
   (15)

The solid-state imaging apparatus according to any one of (1) to (15), wherein
the transfer transistor is configured as a vertical transistor made of polycrystalline silicon.
   (16)

The solid-state imaging apparatus according to (15), wherein
a vertical structure of the transfer transistor partially has a gap in a surface in a depth direction of the pixel.
   (17)

The solid-state imaging apparatus according to any one of (1) to (16), wherein
the shielding portion is a dummy transistor having a semiconductor stacked structure made of polycrystalline silicon.
   (18)

The solid-state imaging apparatus according to any one of (1) to (17), wherein
a well contact for electrically connecting to a semiconductor conductive region of the pixel is formed near the floating diffusion region.
   (19)

The solid-state imaging apparatus according to any one of (1) to (18), wherein the transfer transistor is configured as a pair of transistors for distributing the charges generated by the photoelectric converter to a pair of the floating diffusion regions at a predetermined timing, respectively.

(20)

A distance image sensor device for acquiring a distance image based on distance information to an object obtained by the solid-state imaging apparatus according to any one of (1) to (19).

### REFERENCE SIGNS LIST

1 Solid-state imaging apparatus
11 Pixel array unit
110 Pixel
111 Pixel separator
112 Light-shielding lid
113, 113a, 113b Shielding portion
114, 114_{TG}, 114_{OFG} Embedded structure
115 Dummy transistor
12 Vertical driver
13 Column processor
14 Horizontal driver
15 System controller
16 Signal processor
17 Data storage unit
18 Pixel driving line
19, VSL Vertical signal line
TG Transfer transistor
FDG Switching transistor
RST Reset transistor
FBEN Feedback enable transistor
FBOP Feedback amplifier circuit
AMP Amplification transistor
SEL Selection transistor
OFG Charge drain transistor
FD Floating diffusion region

1. A solid-state imaging apparatus including a pixel array unit in which a plurality of pixels are arranged in an array, wherein
each of the plurality of pixels includes:
a pixel separator that defines an outer edge shape of the pixel and is formed between the adjacent pixels;
a photoelectric converter that generates an amount of charge corresponding to light incident from the outside;
a plurality of transistors, including a transfer transistor formed at one end of the photoelectric converter to transfer the charge generated by the photoelectric converter;
a floating diffusion region formed around the photoelectric converter to temporarily store the charges generated and transferred by the photoelectric converter; and
a shielding portion formed around the photoelectric converter to block light leaking from the photoelectric converter and directed toward the floating diffusion region, the plurality of transistors further includes:
a reset transistor for resetting a potential of the floating diffusion region; and
a feedback enable transistor connected to a feedback amplifier circuit for canceling out voltage noise of the reset transistor, and
the shielding portion includes a first shielding portion that blocks light directed toward a portion of the floating diffusion region formed near the feedback enable transistor.

2. The solid-state imaging apparatus according to claim 1, wherein
the shielding portion is formed to reflect light leaking from the photoelectric converter toward the photoelectric converter.

3. The solid-state imaging apparatus according to claim 1, wherein
the shielding portion has a bent portion formed along an outer peripheral edge of the photoelectric converter.

4. The solid-state imaging apparatus according to claim 1, wherein
the portion of the floating diffusion region formed near the feedback enable transistor is formed on a distal side of the feedback enable transistor with respect to the photoelectric converter.

5. The solid-state imaging apparatus according to claim 4, wherein
the feedback enable transistor is configured as a vertical transistor made of polycrystalline silicon.

6. The solid-state imaging apparatus according to claim 1, wherein
the portion of the floating diffusion region formed near the feedback enable transistor is formed between a pair of the feedback enable transistors.

7. The solid-state imaging apparatus according to claim 1, wherein
the plurality of transistors further includes a switching transistor formed around the photoelectric converter to electrically couple the floating diffusion region to an additional capacitance, and
the shielding portion further includes a second shielding portion that blocks light directed toward another portion of the floating diffusion region formed near the switching transistor.

8. The solid-state imaging apparatus according to claim 7, wherein
the switching transistor is formed to have a bent portion.

9. The solid-state imaging apparatus according to claim 7, wherein
the switching transistor is configured as a vertical transistor made of polycrystalline silicon.

10. The solid-state imaging apparatus according to claim 7, wherein
the other portion of the floating diffusion region formed near the switching transistor is formed to face between a pair of switching transistors.

11. The solid-state imaging apparatus according to claim 7, wherein
the other portion of the floating diffusion region formed near the switching transistor is formed on a distal side of the switching transistor with respect to the photoelectric converter.

12. The solid-state imaging apparatus according to claim 1, wherein
the plurality of transistors further includes at least one charge drain transistor formed at the other end of the photoelectric converter different from the one end to drain charges remaining in the photoelectric converter.

13. The solid-state imaging apparatus according to claim 12, wherein
the charge drain transistor is configured as a vertical transistor made of polycrystalline silicon.

14. The solid-state imaging apparatus according to claim 13, wherein
a vertical structure of the charge drain transistor partially has a gap in a surface in a depth direction of the pixel.

15. The solid-state imaging apparatus according to claim 1, wherein
the transfer transistor is configured as a vertical transistor made of polycrystalline silicon.

16. The solid-state imaging apparatus according to claim 15, wherein
a vertical structure of the transfer transistor partially has a gap in a surface in a depth direction of the pixel.

17. The solid-state imaging apparatus according to claim 1, wherein
the shielding portion is a dummy transistor having a semiconductor stacked structure made of polycrystalline silicon.

18. The solid-state imaging apparatus according to claim 1, wherein
a well contact for electrically connecting to a semiconductor conductive region of the pixel is formed near the floating diffusion region.

19. The solid-state imaging apparatus according to claim 1, wherein
the transfer transistor is configured as a pair of transistors for distributing the charges generated by the photoelectric converter to a pair of the floating diffusion regions at a predetermined timing, respectively.

20. A distance image sensor device for acquiring a distance image based on distance information to an object obtained by the solid-state imaging apparatus according to claim 1.
